(19) United States
(12) Patent Application Publication
(10) Pub. No.: US 2025/0004667 A1
(43) Pub. Date: Jan. 2, 2025

(54) STORAGE DEVICE AND METHOD OF OPERATING THE SAME

(71) Applicant: SK hynix Inc., Gyeonggi-do (KR)

(72) Inventor: Young Jin BAEK, Gyeonggi-do (KR)

(21) Appl. No.: 18/522,247

(22) Filed: Nov. 29, 2023

(30) Foreign Application Priority Data
Jun. 27, 2023 (KR) 10-2023-0082706

(51) Int. Cl. G06F 3/06

(52) U.S. Cl. CPC G06F 3/0659; G06F 3/0619; G06F 3/064; G06F 3/0673

(57) ABSTRACT

Provided herein may be a storage device and a method of operating the same. The storage device may include a memory device including a plurality of memory blocks, and a memory controller configured to control the memory device to perform a read operation of reading data stored in a memory block selected from the plurality of memory blocks, and to obtain a compensated read count based on a unit read count, indicating a number of times the read operation is performed for a unit time, and a temperature measured for the unit time.

### CROSS-REFERENCE TO RELATED APPLICATION

The present application claims priority under 35 U.S.C. § 119 (a) to Korean patent application number 10-2023-0082706 filed on Jun. 27, 2023, the entire disclosure of which is incorporated by reference herein.

### BACKGROUND

### 1. Field of Invention

Various embodiments of the present disclosure relate to an electronic device, and more particularly to a storage device and a method of operating the storage device.

### 2. Description of Related Art

A storage device may include a memory device for storing data therein and a memory controller for controlling the memory device. The memory controller may control the memory device to perform operations related to data storage, data reading, or data erasure according to a request received from a host (i.e., an external device).

The storage device may be operated in various environments such as polar regions, space environments, and vehicles. When the storage device is operated in a low-temperature environment or a high-temperature environment, the storage device may become vulnerable to read disturb, and thus solutions to prevent read disturb depending on such a temperature environment are required.

### SUMMARY

Various embodiments of the present disclosure are directed to a storage device that compensates for a read count depending on temperature to prevent read disturb, and a method of operating the storage device.

An embodiment of the present disclosure may provide for a storage device. The storage device may include a memory device including a plurality of memory blocks, and a memory controller configured to control the memory device to perform a read operation of reading data stored in a memory block selected from the plurality of memory blocks, and to obtain a compensated read count based on a unit read count, indicating a number of times the read operation is performed for a unit time, and a temperature measured for the unit time.

An embodiment of the present disclosure may provide for a method of operating a storage device. The method may include performing a read operation of reading data stored in a memory block selected from the plurality of memory blocks, obtaining a unit read count indicating a number of times the read operation is performed for a unit time, and obtaining a compensated read count based on a weighted summation of the unit read count and a weight value corresponding to a temperature measured for the unit time.

An embodiment of the present disclosure may provide for a storage device. The storage device may include a memory device including a plurality of memory blocks, and a memory controller configured to control the memory device to perform a read operation of reading data stored in a memory block selected from the plurality of memory blocks, obtain a compensated read count based on a weighted summation of a unit read count, indicating a number of times the read operation is performed for a unit time, and a weight value corresponding to an initial temperature measured for the unit time, and control the memory device to store data, stored in the selected memory block among the plurality of memory blocks, in another memory block when the compensated read count is a threshold count or greater.

An embodiment of the present disclosure may provide for a storage device. The storage device may include a plurality of memory blocks, a temperature sensor configured to measure a temperature for a time unit; and a read counter configured to count, as a unit read count, a number of times a read operation is performed on a memory block selected from the plurality of memory blocks for the unit time, wherein the unit read count is compensated according to the temperature.

### BRIEF DESCRIPTION OF THE DRAWINGS

FIG. 1 is a diagram illustrating a storage device according to an embodiment of the present disclosure.

FIG. 2 is a diagram illustrating an embodiment in which a temperature sensor is included in a memory controller.

FIG. 3A is a diagram illustrating a temperature voltage table according to an embodiment of the present disclosure.

FIG. 3B is a diagram illustrating a temperature weight table according to an embodiment of the present disclosure.

FIG. 4 is a diagram illustrating a compensated read count according to an embodiment of the present disclosure.

FIG. 5A is a diagram illustrating a unit read count for each memory block according to an embodiment of the present disclosure.

FIG. 5B is a diagram illustrating a compensated unit read count for each memory block according to an embodiment of the present disclosure.

FIG. 6 is a diagram illustrating a read reclaim operation according to an embodiment of the present disclosure.

FIG. 7 is a diagram illustrating a temperature sensor included in a memory device according to an embodiment of the present disclosure.

FIG. 8A is a diagram illustrating a temperature sensor included in a memory device according to an embodiment of the present disclosure.

FIG. 8B is a diagram illustrating a temperature table according to an embodiment of the present disclosure.

FIG. 9 is a flowchart illustrating a method of operating a storage device according to an embodiment of the present disclosure.

FIG. 10 is a flowchart illustrating in detail a method of operating a storage device according to an embodiment of the present disclosure.

### DETAILED DESCRIPTION

Specific structural or functional descriptions in the embodiments according to the concept of the present disclosure introduced in this specification are only for description of the embodiments according to the concept of the present disclosure. The embodiments according to the concept of the present disclosure may be practiced in various forms, and should not be construed as being limited to the embodiments described in the specification.

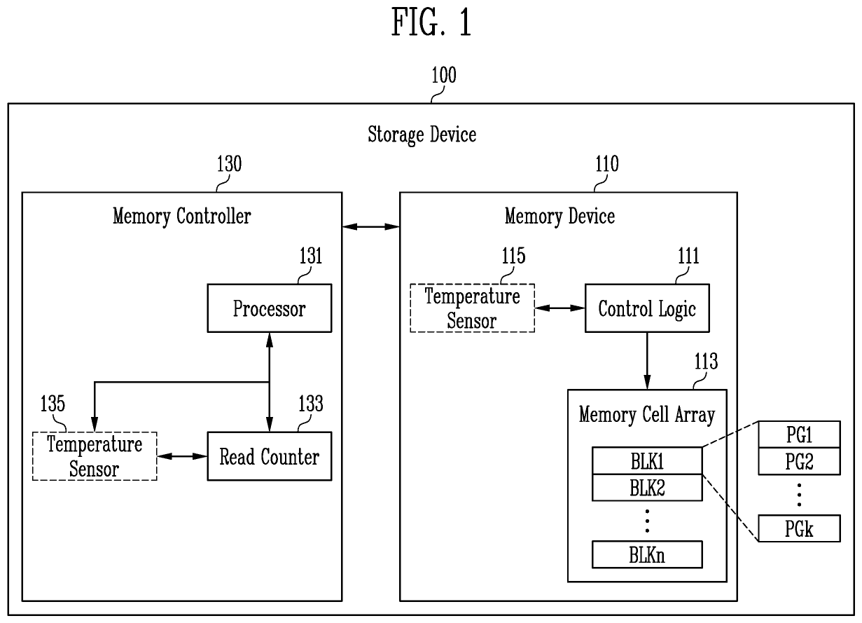

FIG. 1 is a diagram illustrating a storage device 100 according to an embodiment of the present disclosure.

Referring to FIG. 1, the storage device 100 may include a memory device 110 and a memory controller 130. The memory controller 130 may control the memory device 110. In an embodiment, the memory device 110 and the memory controller 130 may be implemented as a single integrated semiconductor package chip or as separate semiconductor package chips.

The memory device 110 may include a control logic 111 and a memory cell array 113.

The control logic 111 may control internal operations of the memory device 110. The memory cell array 113 may include a plurality of memory blocks BLK1 to BLKn. In an embodiment, each of the memory blocks BLK1 to BLKn may include a plurality of pages PG1 to PGk. Here, each page may be the unit by which a write operation or a read operation is performed, and each memory block may be the unit by which an erase operation is performed. Each of the pages PG1 to PGk may include a plurality of memory cells. Each memory cell may store bitwise data. In an embodiment, the memory cell may be, but is not limited to, a NAND flash memory cell, and may be implemented as the cell of any of various types of memories such as a dynamic random access memory (DRAM), a static RAM (SRAM), a magnetic RAM (MRAM), a ferroelectric RAM (FeRAM), a phase-change RAM (PRAM), and a resistive RAM (RRAM).

The control logic 111 may perform an operation corresponding to a command and an address received from the memory controller 130. For example, the address may be a physical address indicating a storage area in the memory cell array 113.

In an embodiment, when a write command, an address, and data are received from the memory controller 130, the control logic 111 may perform a write operation of storing data in the storage area of the memory cell array 113, selected by the address. For example, when the write operation is performed on the first page PG1 of the first memory block BLK1, the control logic 111 may apply a program voltage to the first page PG1 of the first memory block BLK1, and apply a program pass voltage to the remaining pages PG2 to PGk of the first memory block BLK1.

In an embodiment, when a read command and an address are received from the memory controller 130, the control logic 111 may perform a read operation of reading data from the storage area of the memory cell array 113, selected by the address. For example, when a memory block selected by the address is the first memory block BLK1 and a page selected by the address is the first page PG1, the control logic 111 may perform a read operation on the first page PG1 of the first memory block BLK1. During the read operation, the control logic 111 may apply a read voltage to the first page PG1 of the first memory block BLK1 and apply a read pass voltage to the remaining pages PG2 to PGk of the first memory block BLK1.

The memory controller 130 may include a processor 131 and a read counter 133.

The processor 131 may control internal operations of the memory controller 130. In an embodiment, the processor 131 may perform a function of a flash translation layer (FTL). For example, the processor 131 may translate a logical address into a physical address through an address mapping table. The address mapping table may be information including mapping relationships between logical addresses and physical addresses. The processor 131 may generate a command for controlling the operation of the memory device 110. For example, the processor 131 may generate a read command for controlling a read operation or a write command for controlling a write operation. The processor 131 may provide the generated command to the memory device 110.

The read counter 133 may store a read count. The read count may be a value indicating the number of times the memory device 110 performs a read operation. For example, whenever the memory device 110 performs the read operation on the first page PG1 of the first memory block BLK1, the read counter 133 may update (i.e., increase) a read count for the first memory block BLK1. In accordance with various embodiments, the function of the read counter 133 described in the present disclosure may be performed by the processor 131.

In an embodiment, a temperature sensor 115 or 135 may be included in the memory device 110 or the memory controller 130.

Each of the temperature sensors 115 and 135 may measure a temperature. For example, each of the temperature sensors 115 and 135 may be a thermistor circuit including an element, a resistance of which varies with respect to a temperature. Each of the temperature sensors 115 and 135 may measure a resistance (corresponding to a slope of a voltage and a current), and may sense a temperature corresponding to the resistance. This is only an embodiment, and each of the temperature sensors 115 and 135 may be implemented as a sensor such as a thermocouple or an infrared temperature sensor which measures a temperature in various manners.

In an embodiment, the memory controller 130 may obtain a compensated read count. The compensated read count may be a value in which the read count is compensated for depending on a temperature. The compensated read count may be a value that is greater than or less than the number of times the read operation is actually performed.

The present disclosure may provide the storage device 100, which compensates for the read count depending on a temperature and prevents read disturb, and a method of operating the storage device 100. Hereinafter, the present disclosure will be described in detail with reference to the attached drawings.

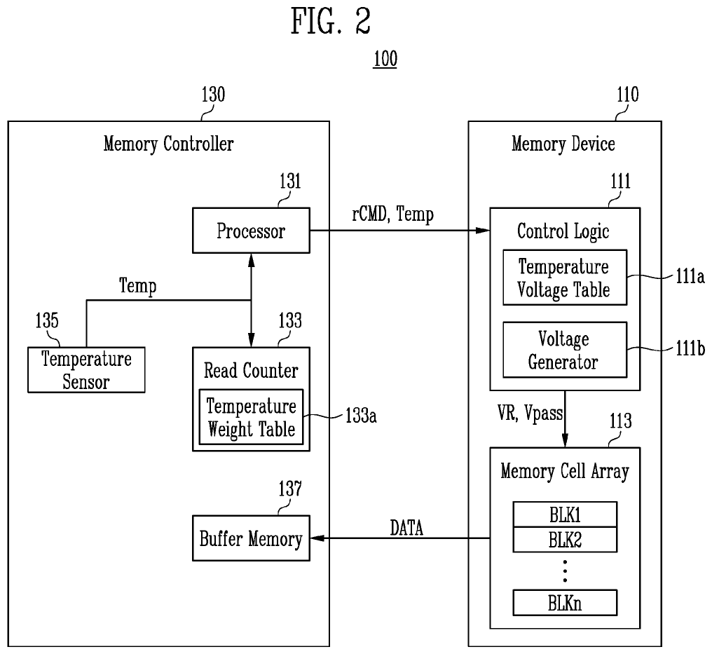

FIG. 2 is a diagram illustrating an embodiment in which a temperature sensor is included in a memory controller.

Referring to FIG. 2, the memory controller 130 of the storage device 100 may include a processor 131, a read counter 133, a temperature sensor 135, and a buffer memory 137. The memory device 110 of the storage device 100 may include a control logic 111 and a memory cell array 113.

The temperature sensor 135 may measure a temperature Temp. In an embodiment, the temperature sensor 135 may measure the temperature Temp at an interval of unit time. For example, the unit time may be a time set to any of various values such as 10, 1, 0.1, and 0.01 seconds. The temperature sensor 135 may transmit the temperature Temp to the processor 131 and the read counter 133.

The processor 131 may control the memory device 110 to perform a read operation of reading data stored in a memory block selected from a plurality of memory blocks BLK1 to BLKn included in the memory cell array 113. For example, the processor 131 may transmit a read command rCMD for controlling a read operation to be performed to the memory device 110. The processor 131 may transmit an address indicating the selected memory block to the memory device 110. In an embodiment, the processor 131 may transmit the temperature Temp that is first sensed by the temperature sensor 135 to the memory device 110.

The control logic 111 may receive the read command rCMD from the memory controller 130. The control logic 111 may receive the address from the memory controller 130.

The control logic 111 may perform a read operation by applying a read voltage VR and a read pass voltage Vpass to the memory cell array 113. For example, the control logic 111 may read data DATA stored in a selected page of the selected memory block, indicated by the address, by applying the read voltage VR to the selected page of the selected memory block and by applying the read pass voltage Vpass to unselected pages of the selected memory block. The read data DATA may be transmitted to the memory controller 130, and may then be stored in the buffer memory 137.

In an embodiment, the control logic 111 may adjust the level of the read pass voltage Vpass depending on the temperature Temp. For example, the control logic 111 may determine a voltage level corresponding to the temperature Temp among a plurality of preset voltage levels as the level of the read pass voltage Vpass. The temperature Temp may be received, together with the read command rCMD, from the memory controller 130.

In an embodiment, the control logic 111 may include a temperature voltage table 111a and a voltage generator 111b. The temperature voltage table 111a may include a plurality of temperature ranges and a plurality of voltage levels which correspond to each other. That is, the control logic 111 may store the temperature voltage table 111a in which corresponding relationships between the temperature ranges and the voltage levels are set. The voltage generator 111b may generate the read voltage VR and the read pass voltage Vpass. The voltage generator 111b may determine a voltage level corresponding to the temperature Temp in the temperature voltage table 111a as the level of the read pass voltage Vpass. During the read operation, the voltage generator 111b may apply the read voltage VR to the selected page of the selected memory block and apply the adjusted read pass voltage Vpass to the unselected pages of the selected memory block.

When the read operation is performed on the selected memory block, the read counter 133 may increase a read count for the selected memory block. For example, the read count for the selected memory block may be the number of times the read operation is performed on the selected memory block since the data was stored in the selected memory block. The read count may be divided into unit read counts depending on the unit time. Each unit read count for the selected memory block may be the number of times the read operation is performed on the selected memory block for the corresponding unit time.

The read counter 133 may obtain a compensated read count based on each unit read count and the temperature Temp for each unit time. In an embodiment, the read counter 133 may include a temperature weight table 133a. The temperature weight table 133a may include a plurality of temperature ranges and a plurality of values which correspond to each other. That is, the read counter 133 may store the temperature weight table 133a in which corresponding relationships between the temperature ranges and the weight values are set. The read counter 133 may determine a weight value corresponding to the temperature Temp in the temperature weight table 133a. The read counter 133 may perform weighted summation of the weight values, corresponding to the temperatures Temp for respective unit times, and unit read counts, and may then acquire a compensated read count.

The buffer memory 137 may store data to be stored in the memory device 110 or data read from the memory device 110. For example, the buffer memory 137 may store the data DATA read from the memory cell array 113 as the read operation is performed. The buffer memory 137 may be, but is not limited to, SRAM or DRAM, and may be implemented as various types of memories. In accordance with various embodiments, the temperature weight table 133a in the present disclosure may be stored and managed in the buffer memory 137.

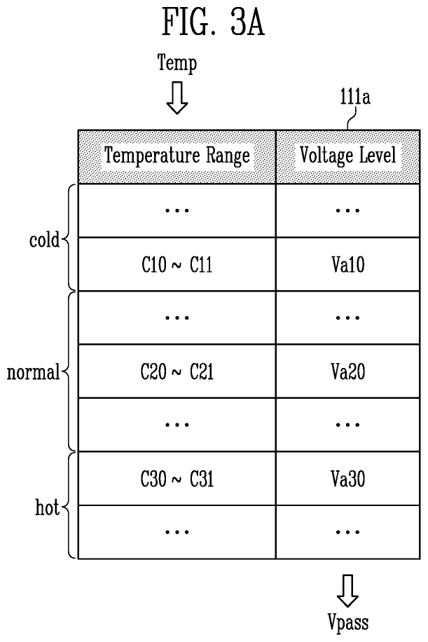

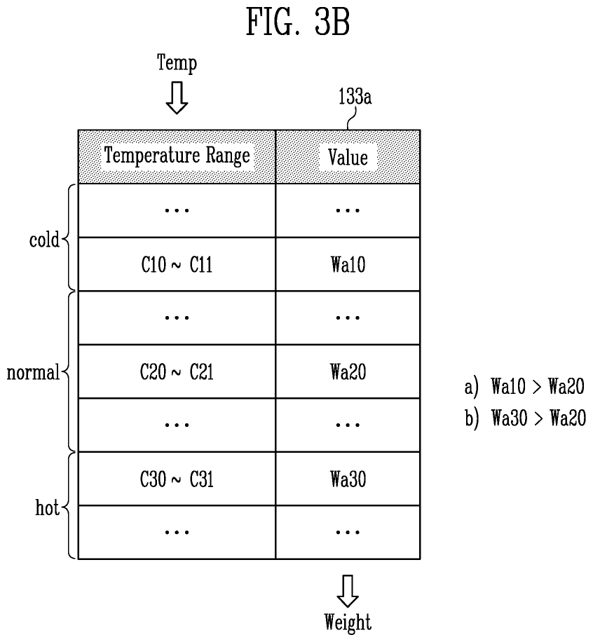

FIG. 3A is a diagram illustrating a temperature voltage table according to an embodiment of the present disclosure. FIG. 3B is a diagram illustrating a temperature weight table according to an embodiment of the present disclosure.

Referring to FIG. 3A, the temperature voltage table 111a may include a plurality of temperature ranges C10 to C11, C20 to C21, and C30 to C31 and a plurality of voltage levels Va10, Va20, and Va30, which correspond to each other. Referring to FIG. 3B, the temperature weight table 133a may include a plurality of temperature ranges C10 to C11, C20 to C21, and C30 to C31 and a plurality of weight values Wa10, Wa20, and Wa30, which correspond to each other.

In an embodiment, the temperature ranges C10 to C11, C20 to C21, and C30 to C31 may not overlap each other. In an example, the respective temperature ranges C10 to C11, C20 to C21, and C30 to C31 may be ranges that are equal to or greater than lower limits C10, C20, and C30 and less than upper limits C11, C21, and C31. In an example, the respective temperature ranges C10 to C11, C20 to C21, and C30 to C31 may be ranges that are greater than the lower limits C10, C20, and C30 and less than or equal to the upper limits C11, C21, and C31. The temperature ranges C10 to C11, C20 to C21, and C30 to C31 may be categorized into a range of a low temperature (cold condition), a range of a normal temperature (normal condition) higher than the lower temperature, and a range of a high temperature (hot condition) higher than the normal range. One voltage level Va10, Va20, or Va30 may correspond to one temperature range C10to C11, C20 to C21, or C30 to C31.

Referring to FIG. 3A, in an embodiment, when a read command is received, the control logic (e.g., 111 of FIG. 2) may determine the level of a read pass voltage Vpass corresponding to a temperature Temp using the temperature voltage table 111a. For example, when the temperature Temp falls within the first temperature range C10 to C11 in the temperature voltage table 111a, the control logic 111 may determine the first voltage level Va10 corresponding to the first temperature range C10 to C11 in the temperature voltage table 111a. The control logic 111 may determine the first voltage level Va10 as the level of the read pass voltage Vpass. That is, the control logic 111 may adjust the read pass voltage Vpass so that the level of the read pass voltage Vpass becomes the first voltage level Va10.

Referring to FIG. 3B, in an embodiment, when a read operation is performed on a selected memory block for a unit time, the read counter (e.g., 133 of FIG. 2) may determine a weight value corresponding to a temperature Temp using the temperature weight table 133a. For example, when the temperature Temp falls within the first temperature range C10 to C11 in the temperature weight table 133a, the read counter 133 may determine the first weight value Wa10 corresponding to the first temperature range C10 to C11 in the temperature weight table 133a.

The read counter 133 may compensate for a unit read count depending on the weight value. Here, the unit read count may indicate the number of times a read operation is performed on the selected memory block for the unit time.

In an embodiment, the first weight value Wa10 corresponding to the first temperature range C10 to C11 for a low temperature may be greater than the second weight value Wa20 corresponding to the second temperature range C20 to C21 for a normal temperature. In an embodiment, the third weight value Wa30 corresponding to the third temperature range C30 to C31 for a high temperature may be greater than the second weight value Wa20 corresponding to the second temperature range C20 to C21 for the normal temperature. In an embodiment, the second weight value Wa20 may be a value of 1, or a value of 1 or less. That is, in the case of the low temperature or high temperature, the degree to which the unit read count is compensated for may be higher than that in the case of the normal temperature.

In an embodiment, the first weight value Wa10 corresponding to the first temperature range C10 to C11 for the low temperature may be greater than the third weight value Wa30 corresponding to the third temperature range C30 to C31 for the high temperature. That is, in the case of the low temperature, the degree to which the unit read count is compensated for may be higher than that in the case of the high temperature.

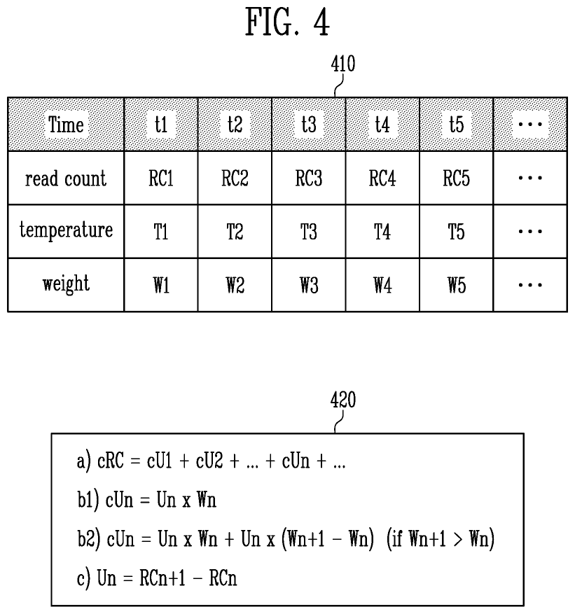

FIG. 4 is a diagram illustrating a compensated read count according to an embodiment of the present disclosure.

Referring to FIG. 4, a table 410 indicates read counts RC1 to RC5,temperatures T1 to T5, and weight values W1 to W5 at specific time points t1 to t5.

Each of the read counts RC1 to RC5 in the table 410 denotes the number of times a read operation is performed on a selected memory block from a time point at which data is stored in the selected memory block to a corresponding specific time point of the specific time points t1 to t5. For example, the first read count RC1 may be the number of times the read operation is performed from the time point at which data is stored to the first time point t1, and the second read count RC2 may be the number of times the read operation is performed from the time point at which data is stored to the second time point t2.

The temperatures T1 to T5 in the table 410 denote values sensed by the temperature sensor at the specific time points t1 to t5. For example, the first temperature T1 may be a value sensed by the temperature sensor at the first time point t1, and the second temperature T2 may be a value sensed by the temperature sensor at the first time point t2. The weight values W1 to W5 in the table 410 denote values corresponding to respective temperatures. For example, the first weight value W1 may be a value corresponding to the first temperature T1, and the second weight value W2may be a value corresponding to the second temperature T2. The weight values W1 to W5 may be determined through the scheme described above with reference to FIG. 3B or the like.

Referring to FIG. 4, in an embodiment, a compensated read count CRC may be calculated based on equations 420. In an embodiment, the compensated read count cRC may be calculated by the memory controller (e.g., 130 of FIG. 2).

The compensated read count cRC may be a value calculated by summing a plurality of compensated unit read counts cU1 to cUn. The plurality of compensated unit read counts cU1 to cUn may include a first compensated unit read count cU1 to an n-th compensated unit read count cUn.

The n-th compensated unit read count cUn may be a value obtained by multiplying the n-th weight value Wn by an n-th unit read count Un. Here, the n-th unit read count Un may be the number of times a read operation is performed for an n-th unit time. The n-th unit time may be a period from an n-th time point to an n+1-th time point. The n-th weight value Wn may be a weight value corresponding to an initial temperature for the n-th unit time. The initial temperature for the n-th unit time may be the temperature that is first sensed within the n-th unit time. For example, the initial temperature for the n-th unit time may be the temperature sensed at the n-th time point.

In an embodiment, when an n+1-th weight value Wn+1 is greater than the n-th weight value Wn, the n-th compensated unit read count cUn may be a value obtained by multiplying the n+1-th weight value Wn+1 by the n-th unit read count Un.

In an embodiment, when the n-th temperature at the n-th time point is higher than the n+1-th temperature at the n+1-th time point, the n-th compensated unit read count cUn may be a value obtained by multiplying the n+1-th weight value Wn+1 by the n-th unit read count Un.

The n-th unit read count Un may be a difference value between the n+1-th read count RCn+1 and the n-th read count RCn. The n+1-th read count RCn+1 may be the number of times the read operation is performed from the time point at which data is stored to the n+1-th time point, and the n-th read count RCn may be the number of times the read operation is performed from the time point at which data is stored to the n-th time point. That is, the n-th unit read count Un may be the change in read count, or the number of times the read operation is performed, from the n-th time point to the n+1-th time point.

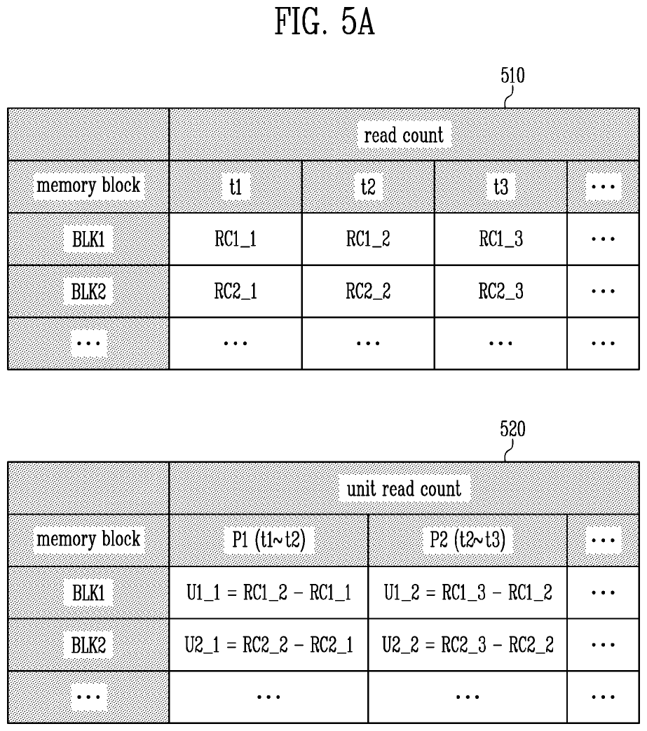

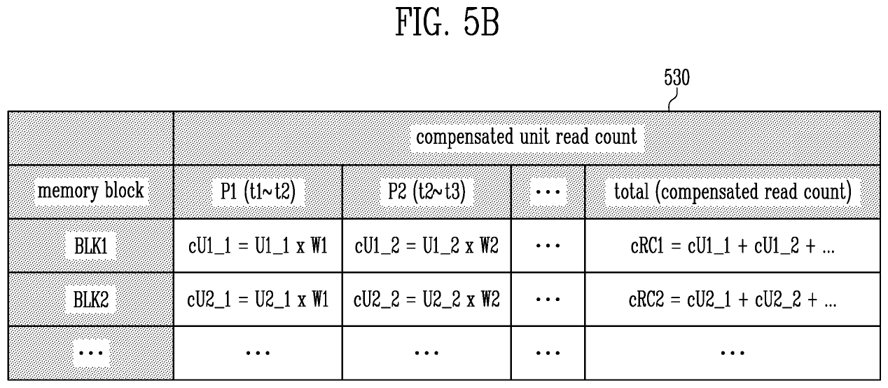

FIG. 5A is a diagram illustrating a unit read count for each memory block according to an embodiment of the present disclosure. FIG. 5B is a diagram illustrating a compensated unit read count for each memory block according to an embodiment of the present disclosure.

Referring to FIG. 5A, a first table 510 shows read counts RC1_1 to RC1_3 and RC2_1 to RC2_3 at specific time points t1 to t3 for respective memory blocks BLK1 and BLK2. A second table 520 shows unit read counts U1_1 to U1_2 and U2_1 to U2_2 for unit times P1 and P2 for respective memory blocks BLK1 and BLK2.

Here, the read counts RC1_1 to RC1_3 and RC2_1 to RC2_3 may be updated on a memory block basis over time. By means of the read counts RC1_1 to RC1_3 and RC2_1 to RC2_3 for respective memory blocks BLK1and BLK2, the unit read counts U1_1 to U1_2 and U2_1 to U2_2 identified depending on the unit times P1 and P2 may be obtained.

For example, the first unit time P1 may be a period from the first time point t1 to the second time point t2, and the second unit time P2 may be a period from the second time point t2 to the third time point t3. In this case, the first unit read count U1_1 for the first memory block BLK1may be a difference value between the second read count RC1_2 at the second time point t2 and the first read count RC1_1 at the first time point t1. That is, the first unit read count U1_1 for the first memory block BLK1may denote the number of times the read operation is performed on the first memory block BLK1 during the first unit time P1 from the first time point t1 to the second time point t2. In the same manner, unit read counts for each memory block may be calculated.

Referring to FIG. 5B, a third table 530 shows compensated unit read counts cU1_1 to cU1_2 and cU2_1 to cU2_2 for unit times P1 and P2 for respective memory blocks BLK1 and BLK2.

The compensated unit read counts cU1_1 to cU1_2 and cU2_1 to cU2_2 may be obtained by multiplying weight values W1 and W2corresponding to the temperatures measured for the unit times by the unit read counts U1_1 to U1_2 and U2_1 to U2_2 for respective memory blocks BLK1 and BLK2.

Each of the compensated read counts cRC1 and cRC2 for respective memory blocks BLK1 and BLK2 may be calculated by summing the compensated unit read counts cU1_1 to cU1_2 or cU2_1 to cU2_2 for the corresponding memory block BLK1 or BLK2.

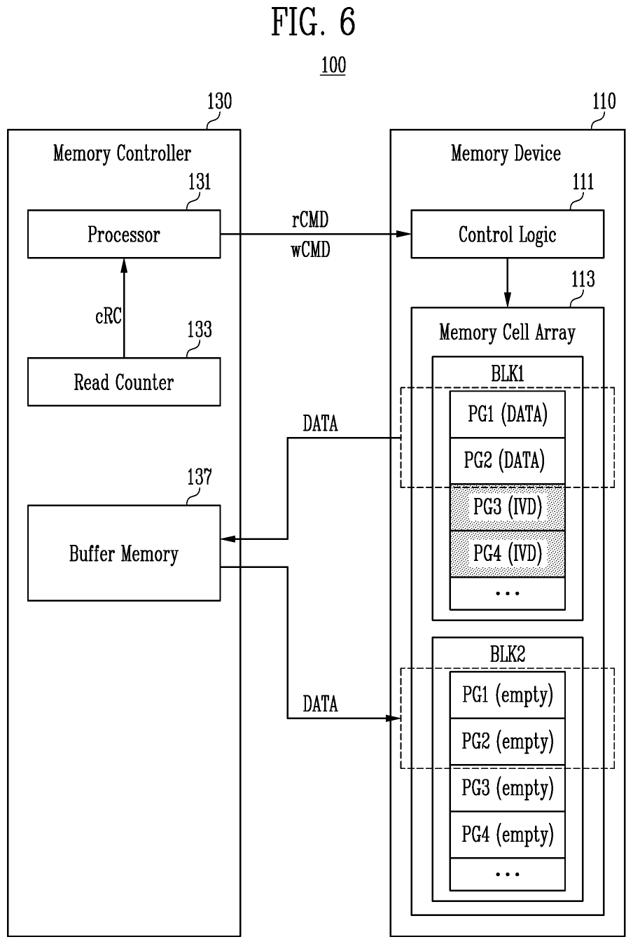

FIG. 6 is a diagram illustrating a read reclaim operation according to an embodiment of the present disclosure.

Referring to FIG. 6, when the compensated read count cRC is equal to or greater than a threshold count, the memory controller 130 may control the memory device 110 to store data, stored in a memory block selected from a plurality of memory blocks (e.g., BLK1 and BLK2), in another memory block.

In an embodiment, the read counter 133 may obtain a compensated read count cRC for each of the memory blocks BLK1 and BLK2. The compensated read count cRC may be calculated by the memory controller 130 or the memory device 110 based on weighted summation of temperatures and unit read counts for respective unit times. The read counter 133 may transfer the compensated read count cRC to the processor 131.

The processor 131 may determine whether the compensated read count cRC for each of the memory blocks BLK1 and BLK2 is equal to or greater than a threshold count. Here, the threshold count may be a preset value. The processor 131 may select a memory block, the compensated read count CRC of which is equal to or greater than the threshold count from the memory blocks BLK1 and BLK2. The processor 131 may control the memory device 110 to perform a read reclaim operation of storing data, stored in the memory block, the compensated read count cRC of which is equal to or greater than the threshold count, in another memory block.

In FIG. 6, the first memory block BLK1 may be a memory block in which the compensated read count cRC is equal to or greater than the threshold count and the second memory block BLK2 is a free block. In this case, the processor 131 may control the memory device 110 to store data, stored in the first memory block BLK1, in the second memory block BLK2.

In detail, the processor 131 may transmit a read command rCMD for controlling data DATA, stored in the first memory block BLK1, to be read to the memory device 110. Here, the data DATA may be valid data. For example, the processor 131 may transmit the address of the pages PG1and PG2 of the first memory block BLK1, in which the data DATA is stored, together with a read command rCMD, to the memory device 110 so that only data DATA other than invalid data IVD is read from the first memory block BLK1. In this case, the control logic 111 may read the data DATA, stored in the first memory block BLK1, and may transmit the data DATA to the memory controller 130. The memory controller 130 may store the received data DATA in the buffer memory 137.

Further, when the reception of the data DATA stored in the first memory block BLK1 is completed, the processor 131 may transmit a write command wCMD for controlling the data DATA to be stored in the second memory block BLK2, together with an address, to the memory device 110. The buffer memory 137 may transmit the data DATA to the second memory block BLK2. In this case, the control logic 111 may control the memory cell array 113 to store the data DATA, received from the memory controller 130, in the second memory block BLK2.

According to the embodiment of the present disclosure, a compensated read count in which the influence of a temperature measured for each unit time period is reflected in the unit read count may be obtained by adjusting the degree to which the unit read count is increased depending on the temperature measured for the unit time. Accordingly, the load of the storage device 100 may be reduced by adjusting the time at which the read reclaim operation is to be performed while preventing read disturb.

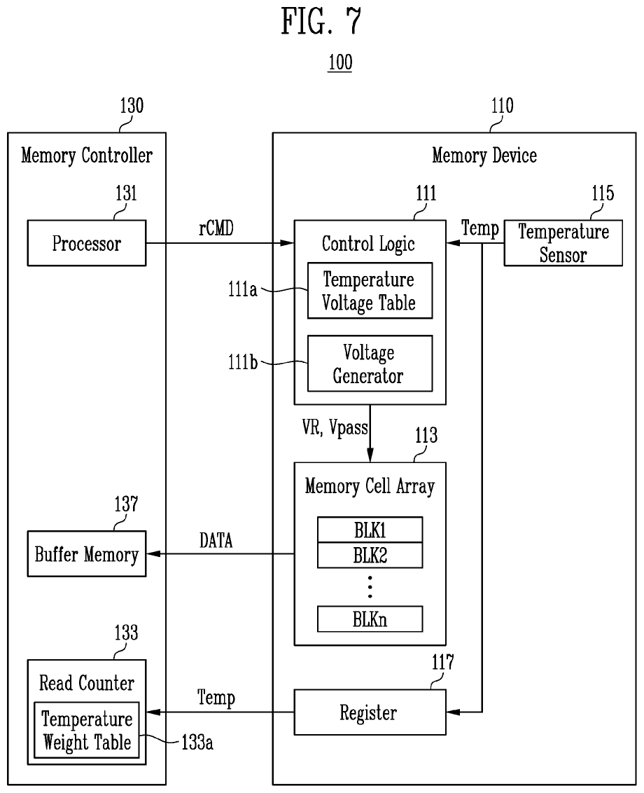

FIG. 7 is a diagram illustrating a temperature sensor included in a memory device according to an embodiment of the present disclosure.

Referring to FIG. 7, the memory controller 130 may include a processor 131, a read counter 133, and a buffer memory 137. The memory device 110 may include a control logic 111, a memory cell array 113, a temperature sensor 115, and a register 117. Information stored in the register 117 may be accessed by the memory controller 130.

The temperature sensor 115 may measure a temperature Temp at an interval of unit time. The temperature sensor 115 may transmit the temperature Temp to the control logic 111 and the register 117. The register 117 may store the temperature Temp. The read counter 133 may obtain the temperature Temp from the register 117.

The processor 131 may transmit a read command rCMD to the memory device 110 so that the memory device 110 performs a read operation of reading data DATA stored in a memory block selected from among a plurality of memory blocks BLK1 to BLKn included in the memory cell array 113. In this case, the processor 131 may transmit an address, together with the read command rCMD, to the memory device 110.

The control logic 111 may receive the read command rCMD from the memory controller 130. In this case, the control logic 111 may receive the address, together with the read command rCMD, from the memory controller 130. The control logic 111 may read data DATA stored in a selected page of the selected memory block, indicated by the address, by applying a read voltage VR to the selected page of the selected memory block and by applying a read pass voltage Vpass to unselected pages of the selected memory block. The read data DATA may be transmitted to the memory controller 130, and may then be stored in the buffer memory 137.

In an embodiment, the control logic 111 may include a temperature voltage table 111a and a voltage generator 111b. The temperature voltage table 111a may include a plurality of temperature ranges and a plurality of voltage levels, which correspond to each other. The voltage generator 111b may generate the read voltage VR and the read pass voltage Vpass. The voltage generator 111b may determine a voltage level corresponding to the temperature Temp in the temperature voltage table 111a as the level of the read pass voltage Vpass.

The read counter 133 includes a temperature weight table 133a including a plurality of temperature ranges and a plurality of values, which correspond to each other. The read counter 133 may receive the temperature Temp from the register 117. The read counter 133 may determine a temperature range within which the temperature Temp falls among the plurality of temperature ranges in the temperature weight table 133a. The read counter 133 may determine a value corresponding to the temperature range, determined in the temperature weight table 133a, as a weight value. The read counter 133 may obtain a compensated unit read count that is a value obtained by multiplying the weight value by a unit read count. The read counter 133 may obtain a compensated read count that is a value calculated by summing a plurality of compensated unit read counts. In accordance with various embodiments, the operation of the read counter 133 described in the present disclosure may be performed by the processor 131. In accordance with various embodiments, the temperature weight table 133a in the present disclosure may be stored and managed in the buffer memory 137.

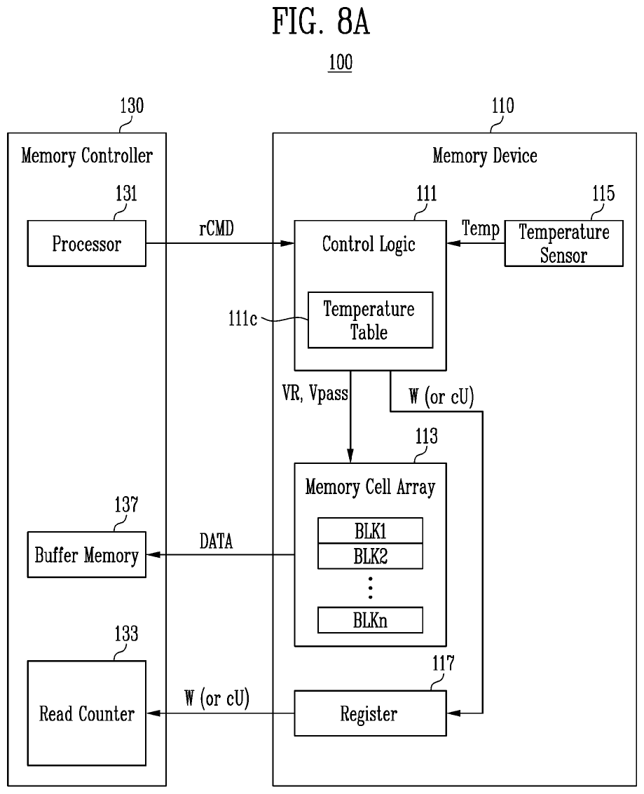

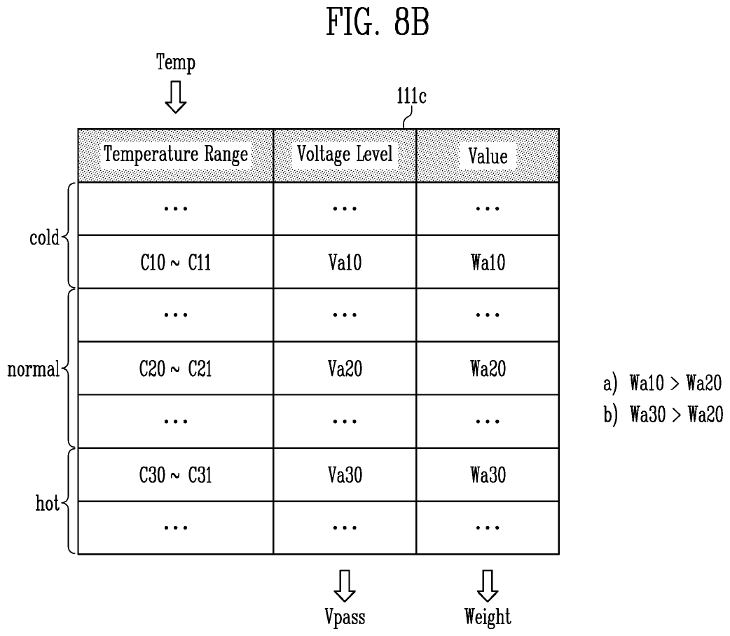

FIG. 8A is a diagram illustrating a temperature sensor included in a memory device according to an embodiment of the present disclosure. FIG. 8B is a diagram illustrating a temperature table according to an embodiment of the present disclosure.

Referring to FIG. 8A, the memory controller 130 may include a processor 131, a read counter 133, and a buffer memory 137. The memory device 110 may include a control logic 111, a memory cell array 113, a temperature sensor 115, and a register 117. The above description may be equally applied to each component, and thus repeated description thereof will be omitted.

Referring to FIGS. 8A and 8B, in an embodiment, the control logic 111 may include a temperature table 111c. The temperature table 111c may include a plurality of temperature ranges C10 to C11, C20 to C21, and C30 to C31, a plurality of voltage levels Va10, Va20, and Va30, and a plurality of values Wa10, Wa20, and Wa30, which correspond to each other.

The control logic 111 may determine a temperature range within which a temperature Temp falls among the plurality of temperature ranges included in the temperature table 111c. The control logic 111 may determine a value corresponding to the determined temperature range as a weight value W corresponding to the temperature Temp. The control logic 111 may determine a voltage level corresponding to the determined temperature range as the level of a read pass voltage Vpass.

In an embodiment, the control logic 111 may transmit the weight value W to the register 117. The register 117 may store the weight value W and transmit the weight value W to the read counter 133. The read counter 133 may obtain a compensated unit read count cU by performing a multiplication of multiplying the weight value W by a unit read count. The read counter 133 may obtain a compensated read count by summing individual compensated unit read counts cU.

In an embodiment, the control logic 111 may update the unit read count whenever a read operation is performed for a unit time. The control logic 111 may obtain the compensated unit read count cU by performing a multiplication of multiplying the weight value W by the unit read count. The control logic 111 may transmit the compensated unit read count cU to the register 117. The register 117 may store the compensated unit read count cU, and may transmit the compensated unit read count cU to the read counter 133. The read counter 133 may obtain the compensated read count by summing individual compensated unit read counts cU received from the register 117.

In an embodiment, the control logic 111 may obtain the compensated read count by summing the compensated unit read counts cU. The control logic 111 may transmit the compensated read count to the register 117. The read counter 133 may receive and obtain the compensated read count from the register 117.

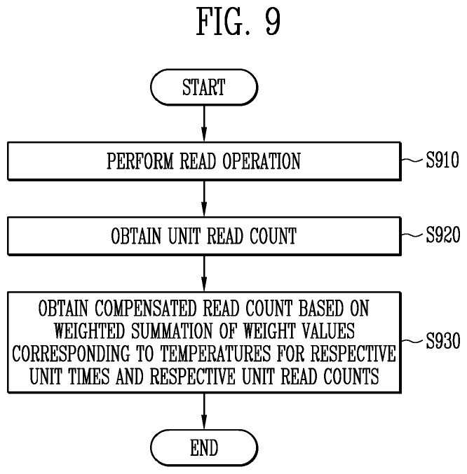

FIG. 9 is a flowchart illustrating a method of operating a storage device according to an embodiment of the present disclosure.

Referring to FIG. 9, the method of operating the storage device may perform a read operation of reading data stored in a memory block selected from a plurality of memory blocks at operation S910. Here, the storage device may include a memory device and a memory controller. The memory device may include a plurality of memory blocks. Each memory block may be selected by an address.

Further, the method of operating the storage device may obtain a unit read count at operation S920. The unit read count for the selected memory block may be the number of times the read operation is performed on the selected memory block for a unit time.

Furthermore, the method of operating the storage device may obtain a compensated read count based on weighted summation of weight values corresponding to temperatures for respective unit times and respective unit read counts at operation S930. The temperature for each unit time may be a temperature that is first obtained within the corresponding unit time. The weighted summation may be an operation of summing result values obtained by multiplying respective unit read counts by weight values.

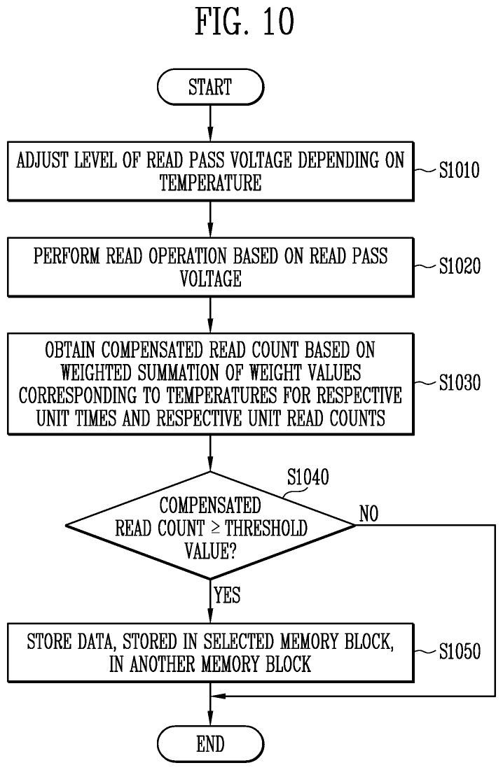

FIG. 10 is a flowchart illustrating in detail a method of operating a storage device according to an embodiment of the present disclosure.

Referring to FIG. 10, the method of operating the storage device may adjust the level of a read pass voltage depending on a temperature at operation S1010. In an embodiment, the temperature may be measured each unit time by a temperature sensor, and may be stored. The temperature sensor may be included in the memory device or the memory controller.

The method of operating the storage device may perform a read operation based on a read pass voltage at operation S1020. The read operation may be an operation of applying a read voltage and the read pass voltage. In an embodiment, the memory device may include a plurality of memory blocks. Each of the memory blocks may include a plurality of pages. The read pass voltage may be applied to unselected pages of a selected memory block. While the read pass voltage is applied, the read voltage may be applied to a selected page of the selected memory block.

Furthermore, the method of operating the storage device may obtain a compensated read count based on a weighted summation of weight values corresponding to temperatures for respective unit times and respective unit read counts at operation S1030.

In an embodiment, the weighted summation may include a multiplication of multiplying a weight value corresponding to a temperature by a unit read count and summation of summing the result values of respective multiplications. The compensated read count may be the result value of the weighted summation. Each unit read count may be obtained by the memory controller or the memory device.

In an embodiment, the method of operating the storage device may further include the operation of storing a temperature weight table and the operation of determining a weight value corresponding to the temperature among a plurality of weight values included in the temperature weight table. The temperature weight table may include a plurality of temperature ranges and a plurality of values, which correspond to each other. The temperature weight table may be stored in the memory device or the memory controller.

In an embodiment, the plurality of weight values included in the temperature weight table may include a first weight value corresponding to a low temperature, a second weight value corresponding to a normal temperature higher than the lower temperature, and a third weight value corresponding to a high temperature higher than the normal temperature. Here, the first weight value may be greater than the second weight value, and the third weight value may be greater than the second weight value. In an embodiment, the first weight value may be greater than the third weight value.

Furthermore, the method of operating the storage device may determine whether the compensated read count is equal to or greater than a threshold value at operation S1040.

When the compensated read count of the selected memory block is equal to or greater than the threshold value (i.e., in the case of Yes at the operation S1040), the method of operating the storage device may store data, stored in the selected memory block, in another memory block at operation S1050. On the other hand, when the compensated read count is not equal to or greater than the threshold value (i.e., in the case of No at the operation S1040), the method of operating the storage device may terminate the operation.

According to embodiments of the present disclosure, the influence of a temperature varying with time may be reflected in a read count. Further, the amount of stress applied to a memory block due to a read pass voltage depending on a temperature may be reflected in the read count.

According to embodiments of the present disclosure, an increment in a read count may be adjusted depending on a temperature for each unit time, whereby the speed at which the read count reaches a threshold value may be dynamically adjusted. Accordingly, the load of the storage device may be reduced by adjusting the time at which a read reclaim operation is to be performed while preventing read disturb.

Embodiments of the present disclosure may provide a storage device that compensates for a read count depending on a temperature and a method of operating the storage device. The present disclosure may provide a storage device that prevents read disturb and a method of operating the storage device.

What is claimed is:

1. A storage device comprising:
a memory device including a plurality of memory blocks; and
a memory controller configured to:
control the memory device to perform a read operation of reading data stored in a memory block selected from the plurality of memory blocks; and
obtain a compensated read count based on a unit read count, indicating a number of times the read operation is performed for a unit time, and a temperature measured for the unit time.

2. The storage device according to claim 1, wherein the memory controller is configured to control the memory device to store data, stored in the selected memory block among the plurality of memory blocks, in another memory block when the compensated read count is a threshold count or greater.

3. The storage device according to claim 1, wherein:
the selected memory block includes a plurality of pages, and
the memory device comprises a control logic configured to adjust a level of a read pass voltage depending on the temperature and to apply a read voltage to a page selected from the plurality of pages and apply the adjusted read pass voltage to an unselected page during the read operation.

4. The storage device according to claim 1, wherein the memory controller comprises a read counter configured to obtain the compensated read count by summing values, each obtained by multiplying the unit read count by a weight value corresponding to the temperature.

5. The storage device according to claim 4, wherein the weight value is a value that corresponds to a temperature range within which the temperature falls in a temperature weight table including a plurality of temperature ranges and a plurality of values, which correspond to each other, the temperature weight table being stored in the memory device or the memory controller.

6. The storage device according to claim 5, wherein:
a plurality of weight values included in the temperature weight table include a first weight value corresponding to a low temperature, a second weight value corresponding to a normal temperature higher than the lower temperature, and a third weight value corresponding to a high temperature higher than the normal temperature, and
the first weight value is greater than the second weight value, and the third weight value is greater than the second weight value.

7. The storage device according to claim 6, wherein the first weight value is greater than the third weight value.

8. The storage device according to claim 4, wherein:
the memory controller further comprises a temperature sensor configured to measure the temperature, and
the read counter includes a temperature weight table including a plurality of temperature ranges and a plurality of values, which correspond to each other, and determines a value corresponding to a temperature range within which the temperature falls in the temperature weight table, as the weight value.

9. The storage device according to claim 4, wherein:
the memory device further comprises:
a temperature sensor configured to measure the temperature; and
a register configured to store the temperature, and
the read counter includes a temperature weight table including a plurality of temperature ranges and a plurality of values, which correspond to each other, and determines, when the temperature is received from the register, a value corresponding to a temperature range within which the temperature falls in the temperature weight table, as the weight value.

10. The storage device according to claim 4, wherein:
the memory device further comprises:
a temperature sensor configured to measure the temperature; and
a control logic configured to store a temperature weight table including a plurality of temperature ranges and a plurality of values, which correspond to each other, and determine a value corresponding to the temperature in the temperature weight table as the weight value, and
the read counter is configured to receive the weight value from the control logic.

11. A method of operating a storage device including a memory controller and a memory device including a plurality of memory blocks, the method comprising:
performing a read operation of reading data stored in a memory block selected from the plurality of memory blocks;
obtaining a unit read count indicating a number of times the read operation is performed for a unit time; and
obtaining a compensated read count based on a weighted summation of the unit read count and a weight value corresponding to a temperature measured for the unit time.

12. The method according to claim 11, wherein obtaining the compensated read count comprises:
performing a multiplication of multiplying the unit read count by a weight value corresponding to the temperature, for each of a plurality of unit times; and
obtaining a value, calculated by summing result values of respective multiplications, as the compensated read count.

13. The method according to claim 12, further comprising:
storing a temperature weight table including a plurality of temperature ranges and a plurality of values, which correspond to each other; and
determining, for each of the plurality of unit times, a value corresponding to the temperature among the plurality of values included the temperature weight table, as the weight value.

14. The method according to claim 13, wherein:
the plurality of weight values included in the temperature weight table include a first weight value corresponding to a low temperature, a second weight value corresponding to a normal temperature higher than the lower temperature, and a third weight value corresponding to a high temperature higher than the normal temperature, and
the first weight value is greater than the second weight value, and the third weight value is greater than the second weight value.

15. The method according to claim 14, wherein the first weight value is greater than the third weight value.

16. The method according to claim 11, further comprising measuring and storing, by a temperature sensor, a temperature each unit time,
wherein the temperature sensor is included in the memory device or the memory controller.

17. The method according to claim 11, further comprising storing data, stored in the selected memory block among the plurality of memory blocks, in another memory block when the compensated read count is a threshold count or greater.

18. The method according to claim 11, wherein performing the read operation comprises:
adjusting a level of a read pass voltage depending on the temperature; and
applying a read voltage to a page selected from a plurality of pages included in the selected memory block and applying a read pass voltage having the adjusted level to an unselected page.

19. A storage device comprising:
a memory device including a plurality of memory blocks; and
a memory controller configured to:
control the memory device to perform a read operation of reading data stored in a memory block selected from the plurality of memory blocks;
obtain a compensated read count based on a weighted summation of a unit read count, indicating a number of times the read operation is performed for a unit time, and a weight value corresponding to an initial temperature measured for the unit time; and
control the memory device to store data, stored in the selected memory block among the plurality of memory blocks, in another memory block when the compensated read count is a threshold count or greater.

20. The storage device according to claim 19, wherein:
the compensated read count is a value calculated by summing a plurality of compensated unit read counts,
the plurality of compensated unit read counts include a first compensated unit read count and a second compensated unit read count,
the first compensated unit read count is a value obtained by multiplying a first weight value corresponding to an initial temperature measured for a first unit time by a first unit read count indicating a number of times the read operation is performed for the first unit time, and
the second compensated unit read count is a value obtained by multiplying a second weight value corresponding to an initial temperature measured for a second unit time by a second unit read count indicating a number of times the read operation is performed for the second unit time.
